(19) United States
(12) Patent Application Publication
(10) Pub. No.: US 2025/0076400 A1
(43) Pub. Date: Mar. 6, 2025

(54) BATTERY MANAGEMENT DEVICE AND METHOD FOR ESTIMATING BATTERY INTERNAL TEMPERATURE

(71) Applicant: BATTLAB INC., Ansan-si (KR)

(72) Inventor: Chul Hyun SIN, Incheon (KR)

(73) Assignee: BATTLAB INC., Ansan-si (KR)

(21) Appl. No.: 18/954,341

(22) Filed: Nov. 20, 2024

Related U.S. Application Data
(63) Continuation of application No. PCT/KR2023/010247, filed on Jul. 18, 2023.

(30) Foreign Application Priority Data
Jul. 18, 2022 (KR) 10-2022-0087934
Jul. 20, 2022 (KR) 10-2022-0089385
Feb. 6, 2023 (KR) 10-2023-0015464

(51) Int. Cl. G01R 31/389; G01R 31/36; G01R 31/367; G01R 31/374; G01R 31/382; G01R 31/392

(52) U.S. Cl. CPC G01R 31/389; G01R 31/3648; G01R 31/367; G01R 31/374; G01R 31/382; G01R 31/392

(57) ABSTRACT

A battery management device includes: an impedance measurement unit that measures impedance of a battery for each frequency band; and a controller that controls the impedance measurement unit to apply a signal of a configured frequency band to the battery, receives a configured impedance corresponding to the configured frequency band from the impedance measurement unit, and inputs the configured impedance to a learning model so as to estimate an internal temperature of the battery, wherein the configured frequency band is determined by a correlation between the impedance for each frequency band and a state of charge (SOC).

### CROSS REFERENCE TO PRIOR APPLICATIONS

This application is a continuation of international application PCT/KR2023/010247 filed on Jul. 18, 2023 which claims priority to Korean Patent Application Nos. 10-2022-0087934 filed on Jul. 18, 2022, 10-2022-0089385 filed on Jul. 20, 2022, and 10-2023-0015464 filed on Feb. 6, 2023. The entire contents of each of the above-identified applications are hereby incorporated by reference.

### BACKGROUND OF THE INVENTION

Embodiments of the present specification relate to a method and apparatus for estimating the internal temperature of a battery using impedance of a specific frequency band.

Today, batteries are designed with high energy density, making fire suppression much more difficult than normal situations. First, if a battery overheats, such as in a runaway, the amount of energy released by the feedback loop that burns an electrolyte in a cell and generates more heat, burning more electrolyte, may be high. Also, during a fire suppression process, battery cells are sealed by battery packs, making it difficult for extinguishing agents to reach the fire area.

Therefore, it is important to continuously monitor the battery status to predict the possibility of a fire in advance. Accordingly, a battery management system (BMS), which is an electronic system that maintains battery cells, modules, racks, or battery packs, manages a battery system so that it can be used safely while performing optimal performance, such as calculating the battery charge status, providing battery surface temperature status and usage history information, protecting against overcharge/overdischarge, and communicating with external devices.

Such BMSs are used in various fields, from small battery products to large battery products such as automobiles and ESS.

The background technology described above is technical information that the inventor possessed for deriving the present invention or acquired during the process of deriving the present invention, and cannot necessarily be said to be technology disclosed to the general public prior to the filing of the present invention.

### SUMMARY OF THE INVENTION

Various embodiments described in this specification, which are proposed to solve the above-described problems, provide a method and apparatus for estimating a battery internal temperature.

A battery management apparatus according to an embodiment of the present specification may include: an impedance measurement unit for measuring frequency band-specific impedance of a battery; and a controller for controlling the impedance measurement unit to apply a signal of a set frequency band to the battery, receiving set impedance corresponding to the set frequency band from the impedance measurement unit, and estimating the internal temperature of the battery by inputting the set impedance into a learning model, wherein the set frequency band is determined by a correlation between the frequency band-specific impedance and a state of charge (SOC).

The learning model may be generated based on a data set including the set impedance and the internal temperature of the battery.

The learning model may be a polynomial regression model between the internal temperature of the battery and the set impedance.

The controller may transmit a fire risk message when the estimated internal temperature of the battery is equal to or greater than a first threshold value.

The controller may perform a fire diagnosis when the estimated internal temperature of the battery is equal to or greater than a second threshold value.

The controller may perform fire management when the amount of phase change of the set impedance over time is equal to or greater than a third threshold value.

A battery management method according to an embodiment of the present specification may include: obtaining set impedance corresponding to a set frequency band from an impedance measurement unit; and estimating the internal temperature of a battery by inputting the set impedance into a learning model, wherein the set frequency band is determined by a correlation between the frequency band-specific impedance and a state of charge (SOC).

The set frequency band may be a frequency band that minimizes the correlation between the frequency band-specific impedance and the state of charge.

The battery management method according to an embodiment may further include transmitting a fire risk message when the estimated internal temperature of the battery is equal to or greater than a first threshold value.

The battery management method according to an embodiment may further include performing a fire diagnosis when the estimated internal temperature of the battery is equal to or greater than a second threshold value.

The performing of the fire diagnosis may include performing fire management when the amount of phase change of the set impedance over time is equal to or greater than a third threshold value.

A method for estimating the internal temperature of a battery according to an embodiment of the present specification may include: setting a battery internal temperature; obtaining frequency band-specific impedance of the battery corresponding to the battery internal temperature from an impedance measurement unit; obtaining a state of charge (SOC) of the battery; determining a set frequency band based on a correlation between the frequency band-specific impedance and the state of charge; determining set impedance corresponding to the set frequency band among the frequency band-specific impedance and the set battery internal temperature as a data set; and generating a learning model for estimating the internal temperature of the battery from the set impedance using the data set.

The learning model may be a polynomial regression model between the internal temperature of the battery and the set impedance.

According to an embodiment of the present invention, it is possible to estimate the internal temperature of a battery and perform battery fire management.

The effects of the present invention are not limited to the effects mentioned above.

### BRIEF DESCRIPTION OF THE DRAWINGS

FIG. 1 is a view for explaining the progress of a battery fire.

FIG. 2 is a view schematically illustrating a management system according to an embodiment of the present invention.

FIG. 3 is a view schematically illustrating a configuration of a battery management apparatus according to an embodiment of the present invention.

FIG. 4 is a flowchart showing a fire estimate operation of a battery management apparatus according to an embodiment of the present invention.

FIG. 5 is a flowchart showing an operation for generating a learning model of a battery management apparatus according to an embodiment of the present invention.

FIGS. 6A to 6D are each a Bode diagram showing a first correlation between frequency band-specific impedance and a state of charge according to an embodiment of the present invention.

FIG. 7 is an RMSE graph according to a frequency band showing a second correlation between frequency band-specific impedance and a state of charge according to an embodiment of the present invention.

FIG. 8 is an RMSE graph according to a frequency band in which a correlation between frequency band-specific impedance and a state of charge is low according to an embodiment of the present invention.

FIG. 9 is a view schematically illustrating a battery pack according to an embodiment of the present invention.

FIG. 10 is view schematically illustrating a battery module according to an embodiment of the present invention.

FIG. 11 is a flowchart showing a fire estimate operation of a battery management apparatus according to an embodiment of the present invention.

FIG. 12 is a flowchart showing an operation for generating a learning model of a battery management apparatus for each module according to an embodiment of the present invention.

FIGS. 13A to 13C are each a view showing a correlation of frequency band-specific impedance of each channel of a specific module.

FIG. 14 is a flowchart showing an operation for generating a learning model of a battery management apparatus for each channel according to an embodiment of the present invention.

FIGS. 15A to 15C are each a view showing a correlation of frequency band-specific impedance of each module of a specific channel.

### DETAILED DESCRIPTION OF THE INVENTION

The present invention may be modified in various ways and has various embodiments, and thus specific embodiments are illustrated in the drawings and to be described in detail in the detailed description. The effects and features of the present invention and the methods for achieving them will become clear with reference to the embodiments described in detail below together with the drawings. However, the present invention is not limited to the embodiments disclosed below and may be implemented in various forms.

Each logical block may represent a module, segment, or a part of a code, which includes one or more executable instructions for executing a specific logical function. It should be noted that in an embodiment, the functions mentioned for each block may be executed in a different order from the order described. For example, even if two blocks are illustrated in succession, the functions described for each block may be executed substantially simultaneously, or may be executed in reverse order depending on different execution conditions or environments. In the following embodiments, singular expressions include plural expressions unless the context clearly indicates otherwise.

In the following embodiments, terms such as include or have mean that the features or components described in this specification exist, and do not exclude the possibility that one or more other features or components may be added.

Instructions executed through a processor of a computer or other programmable data processing equipment may generate means for performing each function described with reference to a flowchart or block diagram. Instructions may be installed on a computer or the like, and may generate processes that are executed on the computer or the like to perform a series of operation steps.

At this time, the term “ . . . unit” used in the present embodiment means a component that performs a specific function performed by software or hardware such as a Field Programmable Gate Array (FPGA) or an Application Specific Integrated Circuit (ASIC). However, “ . . . unit” is not limited to being performed by software or hardware. “ . . . unit” may exist in the form of data stored in an addressable storage medium, or may be configured so that one or more processors perform a specific function.

In the drawings, the sizes of components may be exaggerated or reduced for convenience of explanation. For example, the size and thickness of each configuration shown in the drawings are arbitrarily shown for the convenience of explanation, so the present invention is not necessarily limited to what is shown. In addition, in the present disclosure, the expressions “greater than” and “less than” are used to determine whether a specific condition is satisfied or fulfilled, but they are only a description for expressing an example and do not exclude descriptions of “equal to or greater than” or “equal to or less than”. A condition described as “equal to or greater than” may be replaced with “greater than”, a condition described as “equal to or less than” and a condition described as “equal to or greater than and less than” may be replaced with “greater than and equal to or less than”. Terms such as “first,” “second,” etc. may be used to describe various components, but the components should not be limited by the terms. The terms are used only for the purpose of distinguishing one component from another. Software may include a computer program, code, instructions, or a combination of one or more thereof, and may configure a processing device to operate as desired or independently or collectively command a processing device. The software and/or data may be permanently or temporarily embodied in any type of machine, component, physical device, virtual equipment, computer storage medium or device, or transmitted signal wave, for interpretation by the processing device or for providing instructions or data to the processing device. The software may be distributed on networked computer systems and stored or executed in a distributed manner. The software and data may be stored on one or more computer-readable recording media.

The battery according to the present disclosure is not limited to a specific battery and may indicate a plurality of batteries from a single battery. In addition, the battery according to the present disclosure may be a concept including a battery cell, a battery module, a battery rack, and a battery pack. Therefore, the battery management apparatus according to the present disclosure may perform an internal temperature estimate for the battery cell, the battery module, the battery rack, and the battery pack.

The learning model according to the present disclosure is a model for estimating the temperature inside a battery and may be a machine learning model or a neural network model. At this time, the neural network model is a representative example of an artificial neural network model that simulates brain nerves and is not specified by any algorithm.

The battery internal temperature according to the present disclosure is the internal temperature of a battery, and for example, in the case of a lithium ion battery, it can indicate an internal electrolyte temperature.

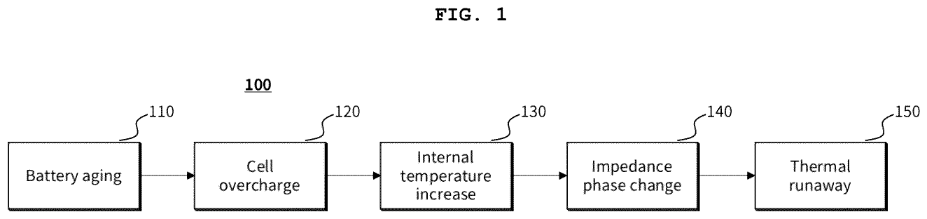

FIG. 1 is a view for explaining the progress of a battery fire.

Referring to FIG. 1, the progress of a typical battery fire is illustrated. The progress of the fire largely goes through the processes of battery aging 110, cell overcharge 120, internal temperature increase 130, impedance phase change 140, and thermal runaway 150. The battery fire according to the present disclosure may specifically indicate a battery fire based on overcharge.

Battery aging 110 is based on chemical and mechanical factors and refers to the process in which the battery life is reduced due to the structure of the battery. For example, in the case of a lithium ion battery, when the battery is used repeatedly, the structure of a negative electrode material changes due to chemical and mechanical causes, and the energy density of the battery decreases. If this process is repeated, the battery life is reduced as it causes a slight change in the graphite structure of the negative electrode material.

Cell overcharge 120 may be caused by battery aging 110, battery state of charge (SOC) estimate error, or ripple voltage. When a battery goes through the overcharge 120 process, a micro-short circuit or electrolyte oxidation-reduction may occur due to overcharged electrode plates.

An internal temperature increase 130 process gradually increases the internal temperature of a battery due to a micro-short circuit or electrolyte oxidation-reduction process due to the overcharge of the battery.

Thereafter, the battery impedance phase undergoes an impedance phase change 140 process in which the battery impedance phase changes rapidly for about 2 to 10 minutes before thermal runaway 150 occurs.

Afterwards, gas from an electrolyte is generated by an electrical and chemical reaction inside the battery, and the internal pressure due to the gas increases, causing venting to occur and then reaching the thermal runaway 150 process.

In this process, if data from the internal temperature increase 130 process is used to predict a fire, efficient battery fire management can be performed, but it is difficult to measure the battery internal temperature, i.e. the temperature of the internal electrolyte, with a general sensor, as it only measures the battery surface temperature.

According to an embodiment of the present invention, disclosed hereinafter is a system for predicting a fire based on a model that estimates the internal temperature of a battery.

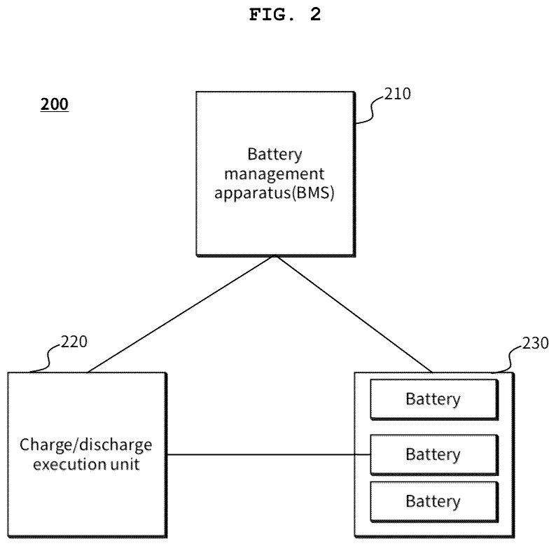

FIG. 2 is a view schematically illustrating a management system 200 according to an embodiment of the present invention.

Referring to FIG. 2, the management system 200 may include a battery management system (BMS) 210, a charge/discharge execution unit 220, and a plurality of batteries 230.

The plurality of batteries 230, which are devices that are targets of internal temperature and fire prediction, may be connected to the charge/discharge execution unit 220 to be charged or discharged, and may be connected to the battery management unit 210 to be managed.

The charge/discharge execution unit 220 may be controlled by the battery management unit 210 to perform charging or discharging on the connected batteries 230.

The battery management unit 210, which is a device that controls battery charging/discharging, may perform battery state of charge (SOC), battery state monitoring, etc. Specifically, the battery management apparatus 210 may perform current, cell voltage, surface temperature, SOC, cell balancing, relay or FET control, fault diagnosis, fire prediction, etc. of the battery 230 mounted on an ESS Energy Storage System, an electric vehicle BEV, etc.

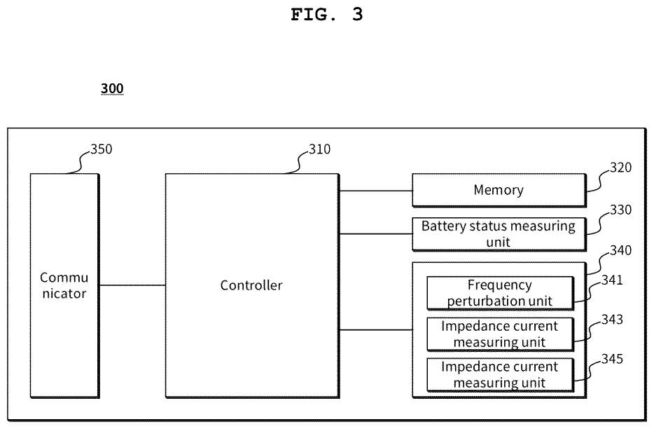

The battery management apparatus 210 according to an embodiment of the present invention may estimate the internal temperature of the battery 230 and perform a fire diagnosis and fire management. Such a battery management apparatus 210 may perform an operation according to an embodiment of the present invention. The battery management apparatus 210 will be described in detail below with reference to FIG. 3.

The management system 200 according to an embodiment of the present invention may include a separate server (not shown). For example, the server may include a learning model, and the battery management apparatus 210 may transmit information about impedance of the battery cell 230 to the server and receive information about the battery internal temperature from the server to manage the battery cell 230.

FIG. 3 is a view schematically illustrating a configuration 300 of a battery management apparatus 210 according to an embodiment of the present invention.

Referring to FIG. 3, the battery management apparatus 210 is illustrated as being composed of a controller 310, a memory 320, a battery status measuring unit 330, an impedance measurement unit 340, and a communication unit 350, but is not necessarily limited thereto. For example, the controller 310, the memory 320, the battery status measuring unit 330, the impedance measurement unit 340, and the communication unit 350 may each exist as physically independent components.

The memory 320 may store various data for the overall operation of the battery management apparatus 210, such as a program for processing or controlling the controller 310 in the battery management apparatus 210. The memory 320 may store a plurality of application programs being driven, data for the operation of the battery management apparatus 210, and commands. The memory 320 may be implemented as an internal memory such as ROM or RAM included in the controller 310 or as a separate memory from the controller 310.

The memory 320 according to an embodiment may store a learning model, current of the battery 230, cell voltage, surface temperature, Soc, etc.

The battery status measuring unit 330 may measure the voltage of a battery cell, cell balancing, and surface temperature of a battery cell. The battery status measuring unit 330 may transmit data sensing the status of a battery to the controller 310.

The impedance measurement unit 340 may measure frequency band-specific impedance of a battery. This impedance measurement unit 340 may be implemented with a frequency perturbation unit 341, an impedance voltage measuring unit 343, and an impedance current measuring unit 345. The impedance measurement unit 340 may measure the impedance of a battery using Electrical Impedance Spectroscopy (EIS). Specifically, the impedance measurement unit 340 may analyze the impedance by measuring the amplitude and phase changes through the impedance voltage and impedance current signals that respond within a range that does not deviate from the electrical equilibrium state and thermal equilibrium state of the battery by applying minute sinusoidal current and voltage signals from a high frequency range to a low frequency range. The impedance measurement unit 340 may analyze the impedance by applying a frequency band indicated by the controller 310 to the battery 230 and transmit at least one of the impedance voltage, impedance current, and impedance to the controller 310. The measuring unit may extract the necessary signal through passive and active filters for the impedance voltage and current. The filter function of the measuring unit may be configured by an IC, an OPAMP, and an RLC element, or may be implemented by an MCU and an RLC element. After passing through the filter, it may be transmitted to an analog-to-digital converter (ADC) of the controller.

The frequency perturbation unit 341 may apply a frequency signal to the battery to measure the frequency band-specific impedance of the battery. The frequency perturbation unit 341 may apply a sinusoidal current and voltage signal for the frequency band instructed by the controller 310.

The impedance voltage measuring unit 343 may measure the impedance voltage of the battery perturbed by the frequency perturbation unit 341. The impedance voltage measuring unit 343 may measure the voltage applied to the battery by the signal applied by the frequency perturbation unit 341.

The impedance current measuring unit 345 may measure the impedance current of the battery perturbed by the frequency perturbation unit 341. The impedance current measuring unit 345 may measure the current flowing through the battery by the signal applied by the frequency perturbation unit 341.

The communication unit 350 performs functions for transmitting and receiving signals through a network.

All or a part of the communication unit 350 may be referred to as a transmitting unit, a receiving unit, or a transceiving unit. The communication unit 350 may provide a function for the battery management apparatus 210 and at least one other node to communicate with each other through a communication network. According to an embodiment of the present disclosure, when a request signal is generated according to a program code stored in a recording device such as the memory 320 of the battery management apparatus 210, the request signal may be transmitted to at least one other node through the communication network under the control of the communication unit 350. Conversely, control signals, commands, contents, files, etc. provided under the control of a processor of at least one other node may be received by the battery management apparatus 210 through the communication unit 350. According to an embodiment, the communication unit 350 may transmit impedance information to the server and receive internal temperature information of the battery from the server.

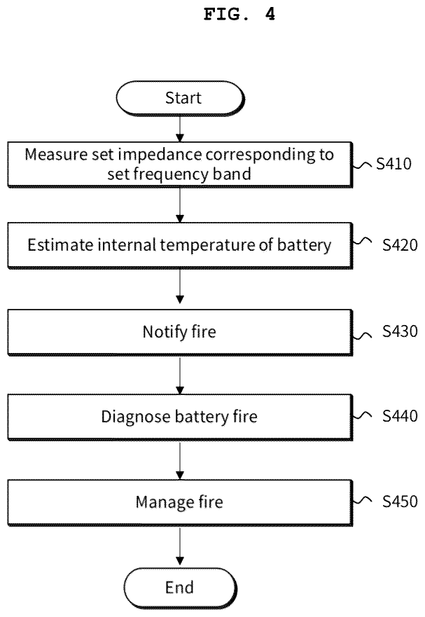

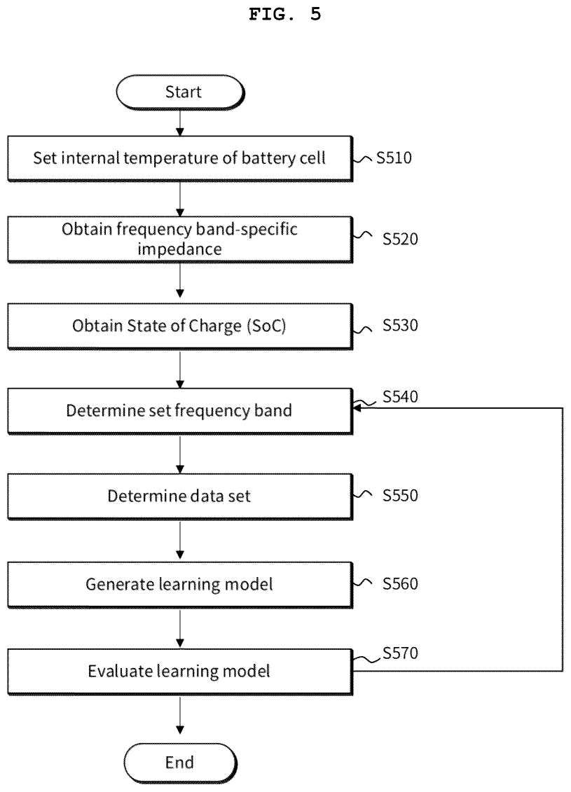

The controller 310 may be a configuration for controlling the battery management apparatus 210 in general. For example, the controller 310 may control the battery management apparatus 210 to perform the operations of FIGS. 4 and 5.

Specifically, the controller 310 may control the operation of the battery management apparatus 210 using various programs stored in the memory 320 of the battery management apparatus 210. The controller 310 may include a CPU, RAM, ROM, system bus, etc. The controller 310 may be implemented as a single CPU or a plurality of CPUs (or DSP, SOC). In an embodiment, the controller 310 may be implemented as a digital signal processor (DSP), a microprocessor, or a time controller (TCON) that processes digital signals. However, the controller 310 is not limited thereto, and may include one or more of a central processing unit (CPU), a micro controller unit (MCU), a micro processing unit (MPU), a controller, an application processor (AP), a communication processor (CP), or an ARM processor, or may be defined by the corresponding term. In addition, the controller 310 may be implemented as a system on chip (SOC), a large scale integration LSI with a built-in processing algorithm, or may be implemented in the form of a field programmable gate array (FPGA).

The controller 310 according to an embodiment may estimate the state of charge SOC of the battery. For example, the controller 310 may estimate the state of charge of the battery based on the voltage of the cell, the cell balancing and the surface temperature of the battery, received from the battery status measuring unit 330. For example, the controller 310 may estimate the state of charge of the battery through the current integration method (Coulomb counting) or estimate various states of the battery using the extended Kalman filter.

The controller 310 according to an embodiment may control the impedance measurement unit 340 to apply a signal of a frequency band to the battery. The controller 310 may receive the impedance voltage and the impedance current from the impedance measurement unit 340 and calculate the impedance using the digital lock-in amplifier principle. In addition, the controller 310 may receive the impedance from the impedance measurement unit 340. This impedance may be expressed through a real number part and an imaginary number part, and the controller 310 may calculate the magnitude and phase of the impedance. In addition, the controller 310 may transmit and receive impedance voltage and impedance current values to and from an external server or cloud through the communication unit 350 and calculate impedance using the Digital Lock In Amplifier principle in the external server and cloud.

According to an embodiment, the controller 310 may control the impedance measurement unit 340 to apply a signal of a set frequency band to the battery and receive measured impedance corresponding to the set frequency band from the impedance measurement unit. At this time, the set frequency band may be determined by the correlation between the frequency band-specific impedance and the state of charge (SOC). Specifically, the set frequency band may indicate a frequency band that minimizes the correlation between the frequency band-specific impedance and the state of charge.

The set frequency band may indicate a frequency band that minimizes the correlation between the frequency band-specific impedance and the state of charge. In other words, this may indicate a frequency band where the frequency band-specific impedance value is maintained constant regardless of the SOC. For example, the controller 310 may generate a learning model that estimates the internal temperature using the SOC and the impedance corresponding to the frequency range, examine the model performance evaluation scores for each SOC with the estimated internal temperature and the actual internal temperature in the process of evaluating the learning model, and set the frequency band with the minimum correlation with the SOC as the set frequency band. The model performance evaluation may be determined by Mean Square Error (MSE), Root Mean Square Error (RMSE), R² score, etc. depending on the machine learning model or neural network model. For example, the controller 310 may determine the frequency band with the minimum average of the RMSE of the internal temperature for each SOC as the set frequency band.

In addition, the controller 310 may determine the frequency band that minimizes the correlation with the SOC as the set frequency band by using the impedance Bode diagram of the battery for each SOC.

The controller 310 as above may also specify the frequency band for multi-modules and multi-channels.

The controller 310 according to another embodiment may control the impedance measurement unit 340 to apply a signal of the set frequency band corresponding to a specific module to the battery, and may receive the measured impedance corresponding to the set frequency band from the impedance measurement unit. At this time, the set frequency band corresponding to the specific module may be determined by the correlation between the frequency band-specific impedance and the channel. Specifically, the set frequency band may indicate the frequency band that minimizes the correlation between the frequency band-specific impedance and the channel.

That is, the set frequency band may indicate a frequency band that minimizes the correlation between the frequency band-specific impedance and the channel. In other words, this may indicate a frequency band in which the frequency band-specific impedance value is maintained constant as the frequency response characteristics are similar regardless of the channel. For example, the controller 310 may generate a learning model that estimates the internal temperature using the impedance corresponding to the channel and the frequency range, examine the channel-specific model performance evaluation scores with the estimated internal temperature and the actual internal temperature in the process of evaluating the learning model, and set the frequency band with the minimum correlation with the channel as the set frequency band. The model performance evaluation may be determined by Mean Square Error (MSE), Root Mean Square Error (RMSE), R² score, etc. depending on the machine learning model or neural network model. For example, the controller 310 may determine the frequency band with the minimum average of the channel-specific RMSE of the internal temperature as the set frequency band.

In addition, the controller 310 may determine a frequency band that minimizes the correlation with the channel as a set frequency band by using the channel-specific impedance Bode diagram of the battery.

According to another embodiment, the controller 310 may control the impedance measurement unit 340 to apply a signal of a set frequency band corresponding to a specific channel to the battery, and may receive a measured impedance corresponding to the set frequency band from the impedance measurement unit. At this time, the set frequency band corresponding to a specific channel may be determined by the correlation between the frequency band-specific impedance and the module. Specifically, the set frequency band may indicate a frequency band that minimizes the correlation between the frequency band-specific impedance and the module.

That is, the set frequency band may indicate a frequency band that minimizes the correlation between the frequency band-specific impedance and the module. In other words, this may indicate a frequency band in which the frequency band-specific impedance value is maintained constant as the frequency response characteristics are similar regardless of the module. For example, the controller 310 may generate a learning model that estimates the internal temperature using the impedance corresponding to the module and the frequency range, examine the module-specific model performance evaluation scores with the estimated internal temperature and the actual internal temperature in the process of evaluating the learning model, and set the frequency band with the minimum correlation with the module as the set frequency band. The model performance evaluation may be determined by Mean Square Error (MSE), Root Mean Square Error (RMSE), Re score, etc. depending on the machine learning model or neural network model. For example, the controller 310 may determine the frequency band with the minimum average of the module-specific RMSE of the internal temperature as the set frequency band.

In addition, the controller 310 may determine the frequency band that minimizes the correlation with the module as the set frequency band using the module-specific impedance Bode diagram of the battery.

An operation of setting the set frequency band will be described in detail in FIGS. 5 to 8 and FIGS. 12 to 15C.

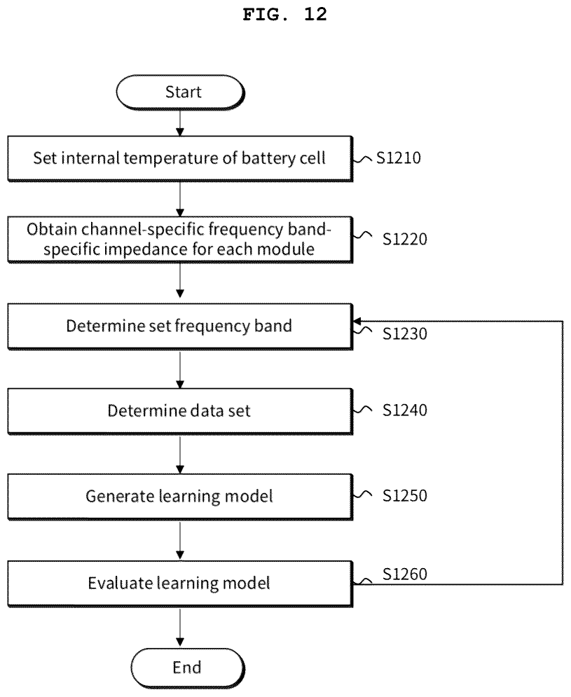

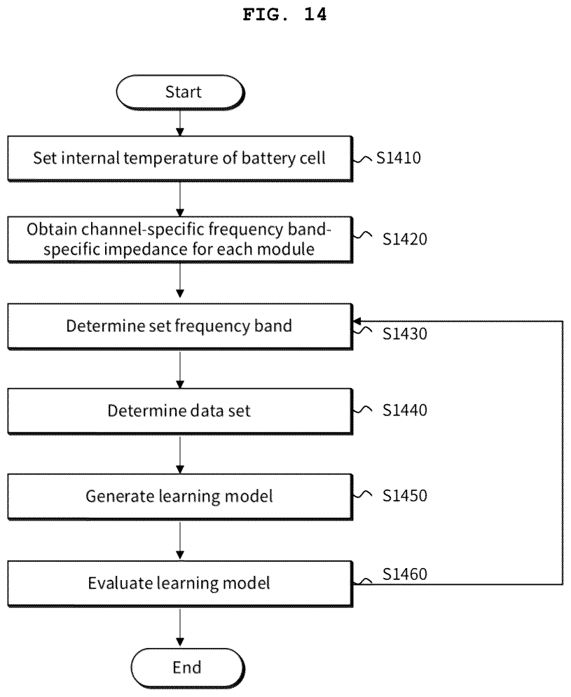

The controller 310 according to an embodiment may estimate the internal temperature of a battery by inputting set impedance into a learning model. An operation of generating such a learning model will be described in detail in FIG. 5, FIG. 12, and FIG. 14.

The learning model is a model that estimates the internal temperature of the battery, for example, the temperature of an electrolyte of the battery, from the set impedance, and may be a model based on a GPR or polynomial regression algorithm.

The controller 310 according to an embodiment may control the battery management apparatus 210 to perform a fire diagnosis based on the estimated internal temperature of the battery. The controller 310 may perform a warning notification for a fire risk if the internal temperature is equal to or greater than a first threshold value. For example, the controller 310 may transmit a risk signal through the communication unit 350 if the estimated internal temperature is equal to or greater than the first threshold value.

The controller 310 may perform a fire diagnosis if the internal temperature is equal to or greater than a second threshold value.

That is, the controller 310 may determine that there is a possibility of a fire occurring from the battery when the internal temperature is equal to or greater than the second threshold value and control the battery management apparatus 210 to enter the fire diagnosis mode. For example, the controller 310 may reduce the monitoring cycle of the battery status measuring unit 330, reduce the SOC estimate cycle, or reduce the battery cooling system cooling cycle when the estimated internal temperature is equal to or greater than the second threshold value. In addition, the controller 310 may increase the charging margin of the battery through charge/discharge control when the internal temperature is equal to or greater than the second threshold value.

The controller 310 according to an embodiment may control the battery management apparatus 210 to perform battery management in the normal mode when the internal temperature is less than the first threshold value.

The controller 310 according to an embodiment may control the battery management apparatus 210 to perform fire management based on the phase change amount of the set impedance. As described above, there may be a rapid change amount in the impedance phase before the thermal runaway, wherein for example, if the change amount in the set impedance phase is equal to or greater than the third threshold value, the controller 310 may determine that the probability of fire occurrence is high and control the battery management apparatus 210 to enter the fire management mode. For example, if the change amount in the set impedance phase is equal to or greater than the third threshold value, the controller 310 may extinguish the battery fire using fire extinguishing equipment. The controller 310 may extinguish the battery fire using a fire extinguishing water supply device or may separate the battery using a separate piece of fire extinguishing water supply equipment.

According to an embodiment, the controller 310 may control the battery management apparatus 210 to perform battery management in the normal mode if the set impedance change is less than the third threshold value.

The fire management mode as described above may be performed independently and in parallel with the fire risk and diagnosis mode, or may be performed dependently on the fire diagnosis mode. For example, the controller 310 according to an embodiment may make control to enter the fire risk mode when the internal temperature is equal to or greater than the first threshold value, enter the fire diagnosis mode when the internal temperature is equal to or greater than the second threshold value in the fire risk mode, and enter the fire management mode when the phase change amount of the impedance in the fire diagnosis mode is equal to or greater than the third threshold value.

The controller 310 according to an embodiment may control the system to enter the general mode when the internal temperature is less than the first threshold value, and may not enter the fire diagnosis mode even when the phase change amount of the impedance in the fire management mode is equal to or greater than the third threshold value. This is to perform a fire prediction based on two variables, the internal temperature of the battery and the phase change amount of the impedance of the battery, to perform a more reliable prediction.

The controller 310 according to an embodiment may generate a learning model. The controller 310 may determine set impedance corresponding to the set frequency band and the set internal temperature of the battery as a data set, and generate a learning model that estimates the internal temperature of the battery from the set impedance using the data set. However, such a learning model may be generated by a separate computing device including at least one of a GPU, a CPU, and a TPU and may be stored in a memory 320 or stored in a separate server.

FIG. 4 is a flowchart showing a fire estimate operation of a battery management apparatus according to an embodiment of the present invention.

Referring to FIG. 4, the battery management apparatus may measure corresponding set impedance in a set frequency band from the impedance measurement unit at step S410. The set frequency band and the specific frequency may be determined by the learning result of FIG. 5. The set frequency band may be determined by the correlation between the frequency band-specific impedance and the state of charge (SOC).

According to an embodiment, the set frequency band may indicate a frequency band that minimizes the correlation between the frequency band-specific impedance and the state of charge. For example, the battery management apparatus may generate a learning model that estimates the internal temperature using the impedance corresponding to the SOC and the frequency band, examine the model performance evaluation scores for each SOC with the estimated internal temperature and the actual internal temperature in the process of evaluating the learning model, and set the frequency band with the minimum correlation with the SOC as the set frequency band. The model performance evaluation may be determined by Mean Square Error (MSE), Root Mean Square Error (RMSE), R² score, etc. depending on the machine learning model or neural network model. For example, the battery management apparatus may determine the frequency band with the minimum average of the RMSE for each SOC of the internal temperature as the set frequency band.

In addition, the battery management apparatus may determine the frequency band that minimizes the correlation between the SOC and the impedance as the set frequency band using the impedance Bode diagram of the battery for each SOC. At this time, the Bode diagram may use at least one of the magnitude Bode diagram and the phase Bode diagram of the impedance.

The battery management apparatus according to an embodiment may estimate the internal temperature of the battery by inputting the set impedance into the learning model at step S420. For example, the battery management apparatus may estimate the internal temperature of the battery by inputting the phase value of the set impedance. The internal temperature of the battery may indicate the temperature of the electrolyte inside the battery.

The learning model according to an embodiment may be generated based on a data set including the set impedance and the internal temperature of the battery.

The battery management apparatus according to an embodiment may perform a battery fire risk notification function at step S430. For example, if the estimated internal temperature of the battery is equal to or greater than the first threshold value, the battery management apparatus may transmit a fire risk notification message through the communication unit 350.

The battery management apparatus according to an embodiment may perform a battery fire diagnosis at step S440. For example, if the estimated internal temperature of the battery is equal to or greater than the second threshold value, the battery management apparatus may perform a fire diagnosis. That is, if the internal temperature is equal to or greater than the second threshold value, the battery management apparatus may determine that there is a possibility of a fire occurring from the battery and enter a mode for a fire diagnosis. For example, if the estimated internal temperature is equal to or greater than the second threshold value, the battery management apparatus may reduce the monitoring cycle of the battery status measuring unit 330, reduce the SOC estimate cycle, or reduce the battery cooling system cooling cycle. In addition, if the internal temperature is equal to or greater than the second threshold value, the battery management apparatus may increase the charging margin of the battery through charge/discharge control. In addition, if the internal temperature is less than the first threshold value, the battery management apparatus according to an embodiment may perform battery management in the normal mode.

In step S450, the battery management apparatus according to an embodiment may perform battery fire management. For example, if the phase change amount of the set impedance is equal to or greater than the third threshold value, the battery management apparatus may determine that there is a high probability of fire occurring and enter a fire management mode. In an embodiment, the battery management apparatus may extinguish the battery fire using fire extinguishing equipment if the change amount of the set impedance is equal to or greater than the third threshold value. The battery management apparatus may extinguish the battery fire using a fire extinguishing water supply device or may separate the battery using a separate piece of fire extinguishing water supply equipment.

The battery management apparatus may perform battery management in the normal mode when the set impedance change amount is less than the third threshold value.

The fire management mode as described above may be performed independently and in parallel with the fire risk and diagnosis mode, or may be performed dependently on the fire diagnosis mode. For example, the battery management apparatus according to an embodiment may make control to enter the fire risk mode when the internal temperature is equal to or greater than the first threshold value, enter the management mode when the internal temperature is equal to or greater than the second threshold value, and enter the fire management mode when the phase change amount of the impedance in the fire management mode is equal to or greater than the third threshold value.

The battery management apparatus according to an embodiment may enter the normal mode when the internal temperature is less than the first threshold value, and may not enter the fire diagnosis mode even when the phase change amount of the impedance in the fire management mode is equal to or greater than the third threshold value. This is to perform a fire prediction based on two variables, the internal temperature of the battery and the phase change amount of the impedance of the battery, to perform a more reliable prediction.

FIG. 5 is a flowchart showing an operation for generating a learning model of a battery management apparatus according to an embodiment of the present invention.

Referring to FIG. 5, the battery management apparatus may set the internal temperature of the battery at step S510. For example, the battery management apparatus may set the internal temperature of the battery by using a separate temperature chamber so that the battery and the chamber temperature are in thermal equilibrium.

The battery management apparatus may obtain the frequency band-specific impedance of the battery corresponding to the battery internal temperature from the impedance measurement unit at step S520. The battery management apparatus may obtain the impedance for the entire frequency range from the impedance measurement unit and store the data.

According to an embodiment, the battery management apparatus may obtain the state of charge (SOC) of the battery at step S530. The battery management apparatus may obtain the state of charge of the battery from the battery status measuring unit or calculate the state of charge of the battery based on the received battery current, cell voltage, and surface temperature of the battery. That is, the battery management apparatus may obtain the frequency band-specific impedance of the battery for each state of charge (SOC) of the battery in steps S510 and S520.

In an embodiment, the battery management apparatus may determine a set frequency band based on the correlation between the frequency band-specific impedance and the state of charge at step S540. In an embodiment, the battery management apparatus may determine a frequency band that minimizes the correlation with the SOC as the set frequency band by using an impedance Bode diagram for each SOC.

In an embodiment, the battery management apparatus may determine set impedance corresponding to the set frequency band among frequency band-specific impedance and a set internal temperature of the battery as a data set at step S550. Specifically, the battery management apparatus may determine a data set using the impedance data corresponding to the set frequency band among the impedance data regarding the entire frequency range as a feature and the internal temperature data of the battery as a label. For example, the battery management apparatus may determine a data set using at least one of the real number part, the imaginary number part, the magnitude, or the phase of the impedance as a feature and the internal temperature data as a label.

In an embodiment, the battery management apparatus may generate a learning model that estimates the internal temperature of the battery from the set impedance using the data set at step S560. The learning model may be a model based on a GPR or polynomial regression algorithm that estimates the internal temperature of the battery from the set impedance.

The battery management apparatus according to an embodiment may evaluate the learning model that estimates the internal temperature of the battery from the set impedance at step S570 and determine the learning model.

The battery management apparatus according to another embodiment may generate a learning model that estimates the internal temperature of the battery from the frequency band-specific impedance at step S560. That is, the battery management apparatus may generate a learning model that estimates the internal temperature using the impedance across the frequency and state of charge.

The battery management apparatus according to another embodiment may evaluate the learning model that estimates the internal temperature using the impedance across the frequency and state of charge at step S570. The learning model performance evaluation may be determined by Mean Square Error (MSE), Root Mean Square Error (RMSE), R² score, etc. depending on the machine learning model or neural network model. Specifically, the battery management apparatus may confirm the Root Mean Square Error (RMSE) for each SOC with the estimated internal temperature and the actual internal temperature.

Thereafter, the battery management apparatus may proceed to step S540 again to determine the frequency band that minimizes the correlation between the frequency band-specific impedance and the state of charge as the set frequency band. For example, the battery management apparatus may determine the frequency band with the minimum average RMSE of the internal temperature by the state of charge (SOC) as the set frequency band. By repeating this process, the set frequency band may be determined and a learning model that estimates the internal temperature of the battery may be generated using the set impedance corresponding to the set frequency band.

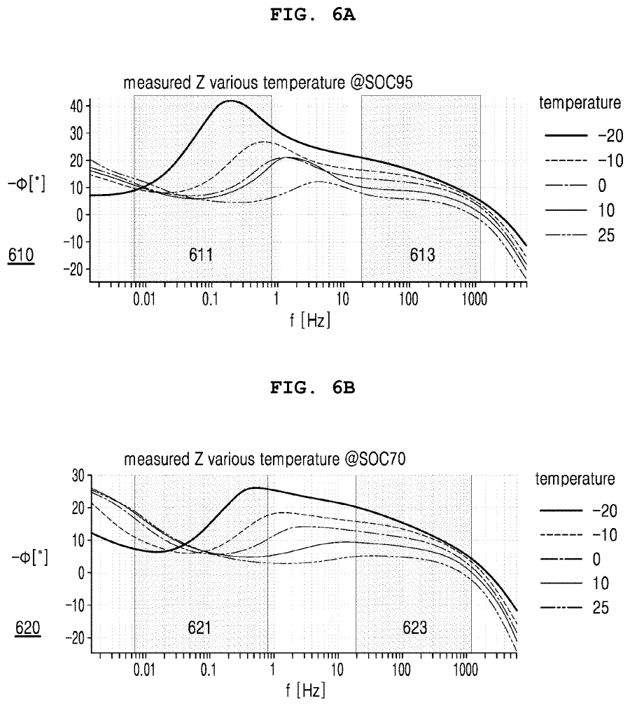

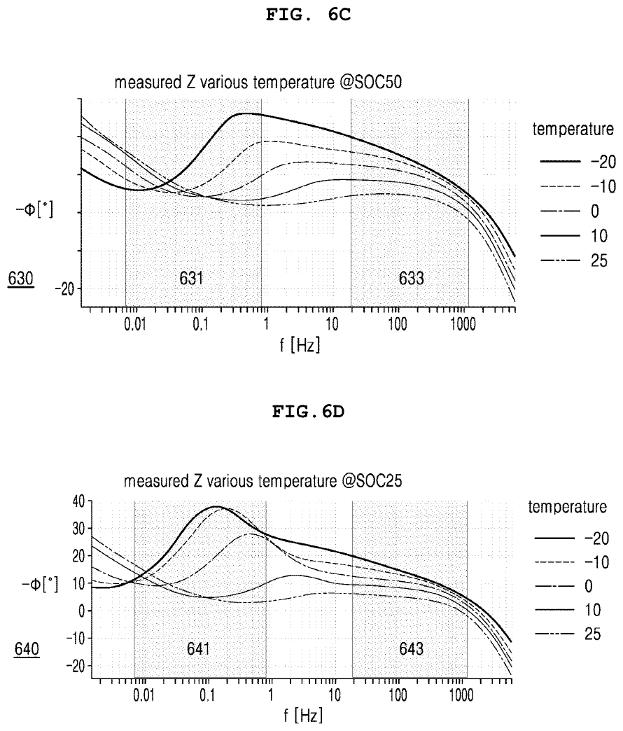

FIGS. 6A to 6D are each a Bode diagram showing a first correlation between frequency band-specific impedance and a state of charge according to an embodiment of the present invention.

As described above, the set frequency band may indicate the frequency band that minimizes the correlation between the frequency band-specific impedance and the state of charge. The battery management apparatus may determine the frequency band that minimizes the correlation with the state of charge (SOC) as the set frequency band using the impedance Bode diagram for each state of charge (SOC).

Referring to FIG. 6A, a first Bode diagram 610 is illustrated regarding the impedance phase according to the internal temperature of the battery when the state of charge (SOC) is 95%; referring to FIG. 6B, a second Bode diagram 620 is illustrated regarding the impedance phase according to the internal temperature of the battery when the state of charge (SOC) is 70%; referring to FIG. 6C, a third Bode diagram 630 is shown regarding the impedance phase according to the internal temperature of the battery when the state of charge (SOC) is 50%; and referring to FIG. 6D, a fourth Bode diagram 640 is shown regarding the impedance phase according to the internal temperature of the battery when the state of charge (SOC) is 25%.

When seeing the phase change according to the state of charge (SOC) in the frequency domain of the Bode diagram, it may be known that the phase values according to the temperature are shown to be similar regardless of the state of charge (SOC) in a band from 20 hz to 1 kHz. Specifically, when comparing the impedance phase 611 in the first frequency band of the first Bode diagram 610, the impedance phase 621 in the first frequency band of the second Bode diagram 620, the impedance phase 631 in the first frequency band of the third Bode diagram 630, and the impedance phase 641 in the first frequency band of the fourth Bode diagram 640, it may be known that there is a correlation with the state of charge (SOC) in the relationship between the impedance and temperature. However, when comparing the impedance phase 613 in the second frequency band of the first Bode diagram 610, the impedance phase 623 in the second frequency band of the second Bode diagram 620, the impedance phase 633 in the second frequency band of the third Bode diagram 630, and the impedance phase 643 in the second frequency band of the fourth Bode diagram 640, it may be known that there is a relatively low correlation with the state of charge (SOC) in the relationship between the impedance and temperature. Accordingly, the battery management apparatus may determine the second frequency band, which has a relatively low correlation in the state of charge (SOC) in the relationship between the impedance and temperature, as the set frequency band.

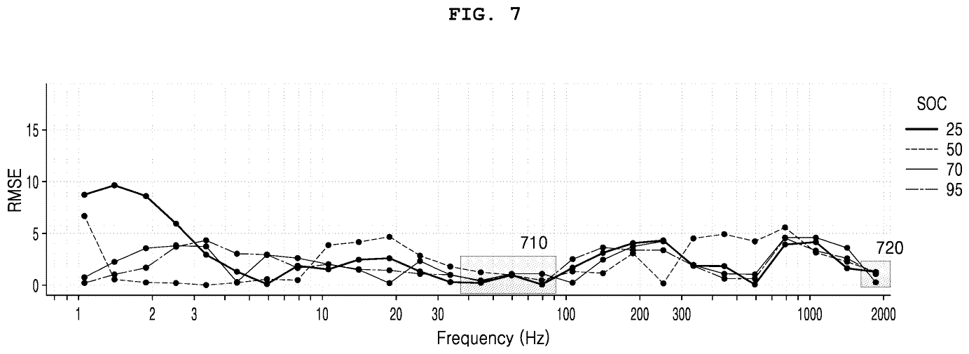

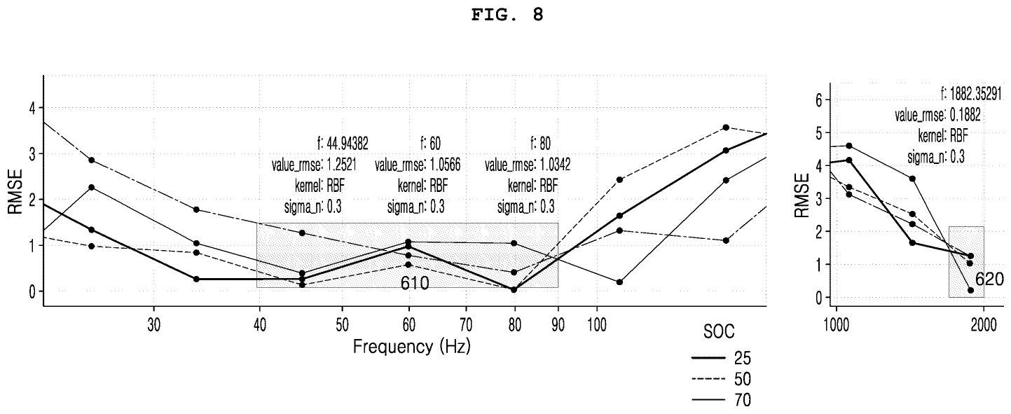

FIG. 7 is an RMSE graph according to a frequency band showing a second correlation between frequency band-specific impedance and a state of charge according to an embodiment of the present invention, and FIG. 8 is an RMSE graph according to a frequency band in which a correlation between frequency band-specific impedance and a state of charge is low according to an embodiment of the present invention.

As described above, the set frequency band may indicate the frequency band that minimizes the correlation between the frequency band-specific impedance and the state of charge. The battery management apparatus may determine the frequency band with the minimum average of the RMSE for each state of charge (SOC) of the internal temperature as the set frequency band.

The battery management apparatus may generate a learning model that estimates the internal temperature using the state of charge (SOC) and the impedance corresponding to the frequency range, examine the RMSE for each state of charge (SOC) with the estimated internal temperature and the actual internal temperature in the process of evaluating the learning model, and set the frequency band with the minimum correlation with the state of charge (SOC) as the set frequency band.

Referring to FIGS. 7 and 8, the RMSE value of the state of charge (SOC) of the internal temperature has the minimum value in a first section 710 and a second section 720. Accordingly, the battery management apparatus may determine one of the first section 710 and the second section 720 as the set frequency band. The battery management apparatus may narrow or widen the set frequency band by repeatedly performing this process. For example, the set frequency band may be a 40 hz to 80 hz band or a specific frequency may be 44 Hz.

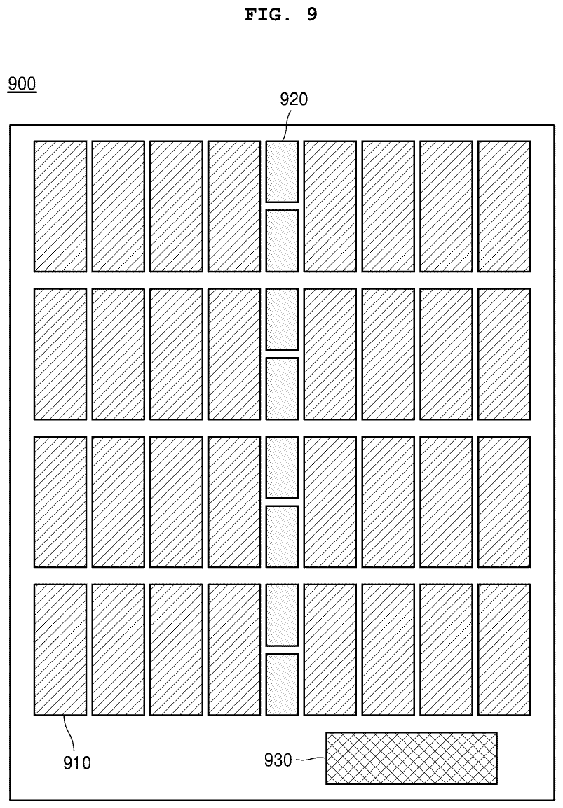

FIG. 9 is a view schematically illustrating a battery pack according to an embodiment of the present invention. FIG. 9 is a battery management system for a battery pack 900, having a plurality of battery modules and a plurality of channels, wherein the system may include a plurality of battery modules 910, battery management units (BMU) 930, and cell management (monitoring) units (CMU) 920.

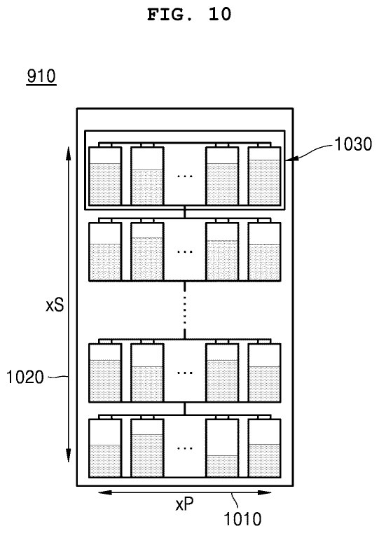

FIG. 9 as such may correspond to a part of the configuration of FIG. 2. For example, the battery module 910 may be composed of a plurality of batteries 230, and the battery module 910 will be described in detail with reference to FIG. 10. The plurality of CMUs 920 and the plurality of BMUs 930 may be combined to perform at least one operation of the battery management apparatus 210.

The CMU 920 may monitor and manage battery cells. This may measure the voltage, temperature, and impedance of each battery cell and transmit the data to the BMU 930. The CMU 920 manages battery modules, and for example, a single CMU 920 may manage two to four to eight battery modules 910.

The BMU 930 may monitor and manage the status of the entire battery system. Data may be received from each of the plurality of CMUs 920 and based thereon, the state of charge (SOC) and state of health (SOH) of the entire battery pack may be estimated. In addition, the BMU 930 may protect the battery in situations such as overcharge, overdischarge, and overheat. The BMU 930 may specifically determine a set frequency band for each of the multi-modules and multi-channels or measure a set impedance value in the set frequency band to perform battery internal temperature estimate.

FIG. 10 is view schematically illustrating a battery module according to an embodiment of the present invention. Referring to FIG. 10, one battery module 910 may include a plurality of battery cells 1001. Specifically, the battery module 910 may have series and parallel connection of a plurality of battery cells 1001. For example, a battery module 910 in which battery cells xPs 1010 are connected in parallel and battery cells xSs 1020 are connected in series may be referred to as an xPxS battery module, and such a unit of serial connection of battery cells 1001 may be referred to as a channel 1030. For example, a 2P6S battery module 910 may have a total of six channels. Likewise, a case where there are a plurality of battery modules 910 may be referred to as a multi-module, multi-channel battery system.

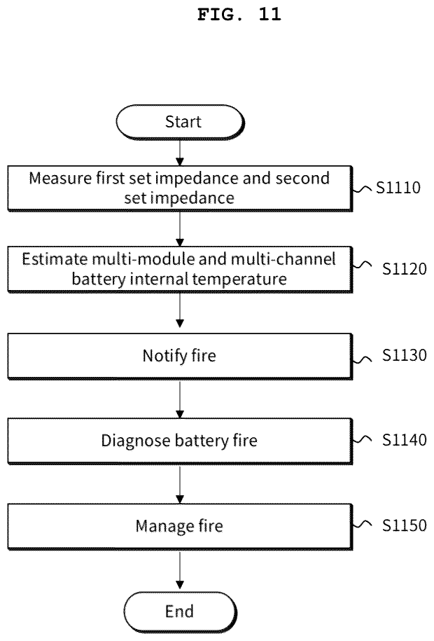

FIG. 11 is a flowchart showing a fire estimate operation of a battery management apparatus according to an embodiment of the present invention.

Referring to FIG. 11, at step S1110, the battery management apparatus may measure corresponding first set impedance in a first set frequency band for a specific module from the impedance measurement unit, and may measure a corresponding second set impedance in a second set frequency band for a specific channel. For example, if the first set impedance band is 20 hz, the impedance for the corresponding band may be measured, and if the second set impedance band is 100 hz, the impedance for the corresponding band may be measured, respectively.

This first set impedance may be determined by the learning result of FIG. 12, and the second set impedance may be determined by the learning result of FIG. 14.

The first set frequency band may be calculated from the channel-specific frequency band-specific impedance for each battery module. For example, the first set frequency band may be determined by the correlation between the frequency band-specific impedance and the channel.

For example, the battery management apparatus may generate a first learning model that estimates the internal temperature using the channel-specific frequency band-specific impedance for each battery module, examine the channel-specific model performance evaluation score with the estimated internal temperature and the actual inside in the process of evaluating and set the frequency band with the minimum the model, correlation with the channel as the set frequency band. Alternatively, the frequency band that minimizes the correlation between the channel and the impedance may be determined as the set frequency band using the channel-specific frequency band-specific impedance Bode diagram or Nyquist plot. At this time, the Bode diagram may use at least one of the magnitude Bode diagram and the phase Bode diagram of the impedance. The model performance evaluation may be determined by Mean Square Error (MSE), Root Mean Square Error (RMSE), R² score, etc. depending on the machine learning model or neural network model.

In addition, the second set frequency band may be calculated from the module-specific frequency band-specific impedance for each battery channel. For example, the second set frequency band may be determined by the correlation between the frequency band-specific impedance and the module.

For example, the battery management apparatus may generate a second learning model that estimates the internal temperature using the module-specific frequency band-specific impedance for each battery channel, examine the channel-specific model performance evaluation scores with the estimated internal temperature and the actual inside in the process of evaluating the model, and set the frequency band with the minimum correlation with the module as the set frequency band. Alternatively, the frequency band that minimizes the correlation between the module and the impedance may be determined as the set frequency band using the module-specific frequency band-specific impedance Bode diagram or Nyquist plot. At this time, the Bode diagram may use at least one of the magnitude Bode diagram and the phase Bode diagram of the impedance. The model performance evaluation may be determined by Mean Square Error (MSE), Root Mean Square Error (RMSE), R2 score, etc. depending on the machine learning model or neural network model.

The battery management apparatus according to an embodiment may estimate the internal temperature of the battery by inputting the first set impedance into the first learning model and the second set impedance into the second learning model at step S1120. The internal temperature of the battery may indicate the temperature of the electrolyte inside the battery.

For example, the battery management apparatus may use the first internal temperature estimated by the first learning model and the second internal temperature estimated by the second learning model with different weights for the internal temperature estimate. This may be expressed by equation 1.

$$T = {aT}_{1} + ( 1 - a ) {T}_{2} \qquad [ Equation l ]$$

T is the estimated internal temperature, T₁ is the first internal temperature, T₂ is the second internal temperature, and a is the weight. That is, the battery management apparatus the first internal temperature

For example, the battery management apparatus may, in the battery pack composed of thirty-two 2P6S modules, i) measure the impedance of battery module No. 8 with the first set frequency band corresponding to battery module No. 8 and input the same into the first learning model, and ii) measure the impedance of channel 3 with the second set frequency band corresponding to channel 3 and input the same into the second learning model, thereby estimating the internal temperature of channel 3 of battery module No. 8.

For the following steps S1130 to S1150, any redundant descriptions described in steps $430 to S450 of FIG. 4 will be omitted.

FIG. 12 is a flowchart showing an operation for generating a learning model of a battery management apparatus for each module according to an embodiment of the present invention.

Referring to FIG. 12, the battery management apparatus may set the internal temperature of the battery at step S1210. For example, the battery management apparatus may set the internal temperature of the battery by using a separate temperature chamber so that the battery and the chamber temperature are in thermal equilibrium.

The battery management apparatus may obtain the channel-specific frequency band-specific impedance for each battery module from the impedance measurement unit at step S1220. The battery management apparatus may obtain the channel-specific frequency range impedance for each battery module from the impedance measurement unit and store the data.

In an embodiment, the battery management apparatus may determine a set frequency band corresponding to a specific battery module based on the frequency band-specific impedance and channel-specific correlation at step S1230.

In an embodiment, the battery management apparatus may determine a frequency band that minimizes the correlation with the channel as the set frequency band using the channel-specific impedance Bode diagram or Nyquist plot. In each battery module, a set frequency band in which the frequency response characteristics of all channels are similar may be determined and used for the internal temperature estimate.

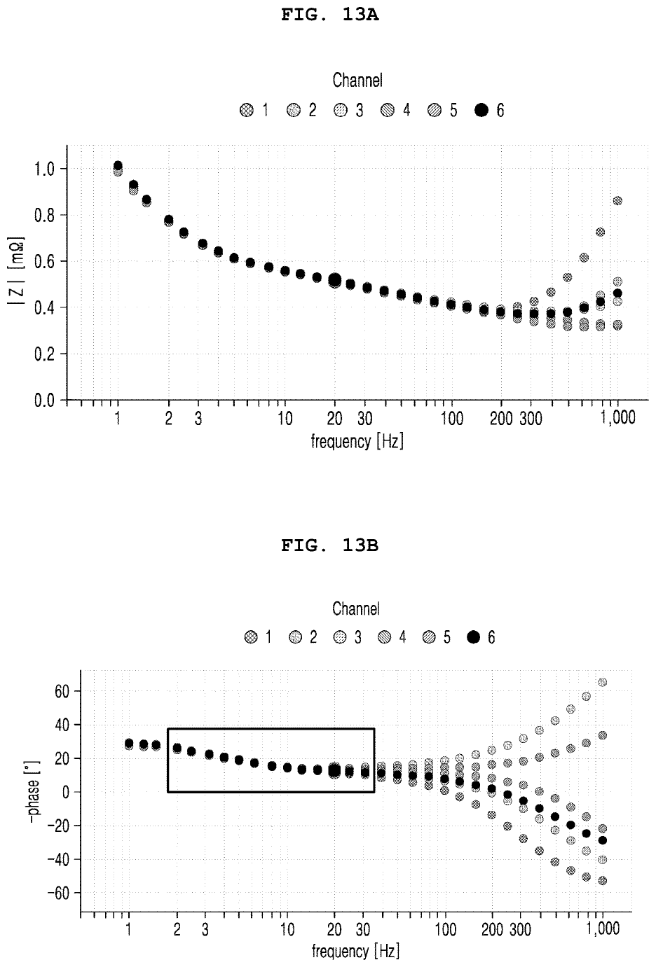

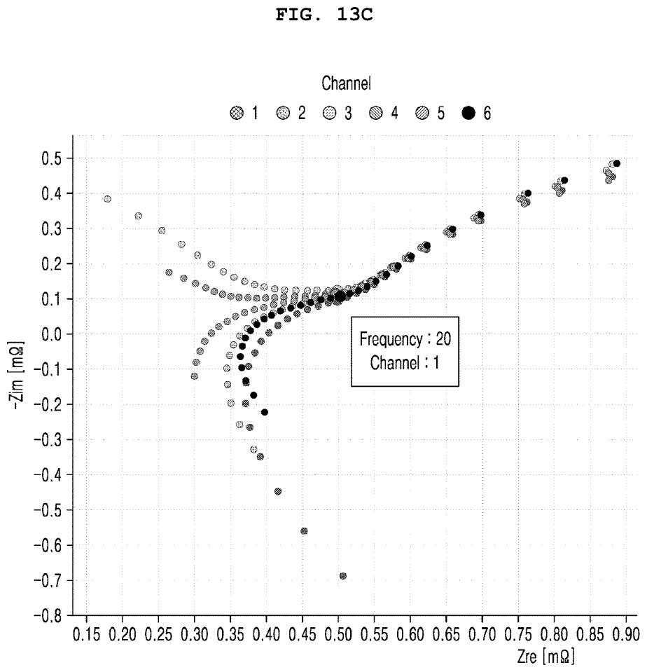

For example, the battery management apparatus may identify a Bode diagram for the magnitude of frequency band-specific impedance with a channel-specific legend of a specific battery module in the battery pack, as illustrated in FIG. 13A. At this time, it may be confirmed that the correlation between the channel and the impedance magnitude is low in a frequency band of 2 hz to 30 hz. The battery management apparatus may determine a set frequency band corresponding to a specific battery module in a frequency band with a low correlation between the channel and the impedance magnitude.

The battery management apparatus may identify a Bode diagram for the phase of frequency band-specific impedance with a channel-specific legend of a specific battery module in the battery pack, as illustrated in FIG. 13B. At this time, it may be confirmed that the correlation between the channel and the impedance phase is low in a frequency band of 2 hz to 30 hz. The battery management apparatus may determine a set frequency band corresponding to a specific battery module in the frequency band with a low correlation between the channel and the impedance phase.

The battery management apparatus may identify the Nyquest plot for the phase of frequency band-specific impedance with a channel-specific legend of a specific battery module in the battery pack, as illustrated in FIG. 13C. At this time, it may be confirmed that the correlation between the channel and the impedance is low in a frequency band of 2 hz to 30 hz. The battery management apparatus may determine a set frequency band corresponding to a specific battery module in the frequency band with a low correlation between the channel and the impedance.

In an embodiment, the battery management apparatus may determine set impedance corresponding to the set frequency band among frequency band-specific impedance and a set internal temperature of the battery as a data set at step S1240. Specifically, the battery management apparatus may determine a data set using the impedance data corresponding to the set frequency band among the impedance data regarding the entire frequency range as a feature and the internal temperature data of the battery as a label. For example, the battery management apparatus may determine a data set using at least one of the real number part, the imaginary number part, the magnitude, or the phase of the impedance as a feature and the internal temperature data as a label.

In an embodiment, the battery management apparatus may generate a learning model that estimates the internal temperature of the battery from the set impedance using the data set at step S1250. The learning model is a model that estimates the internal temperature of the battery from the set impedance corresponding to a specific battery module, and may be a model based on a GPR or polynomial regression algorithm.

The battery management apparatus according to an embodiment may evaluate the learning model that estimates the internal temperature of the battery from the set impedance at step S1260 and determine the learning model.

The battery management apparatus according to another embodiment may generate a learning model that estimates the internal temperature of the battery from the frequency band-specific impedance at step S1250. That is, the battery management apparatus may generate a learning model that estimates the internal temperature using the impedance across the frequency and channel.

In another embodiment, the battery management apparatus may evaluate the learning model that estimates the internal temperature using the impedance across the frequency and channel at step S1260. The model performance evaluation may be determined by Mean Square Error (MSE), Root Mean Square Error (RMSE), R2 score, etc. depending on the machine learning model or neural network model. Specifically, the battery management apparatus may confirm the Root Mean Square Error (RMSE) for each channel with the estimated internal temperature and the actual internal temperature.

Thereafter, the battery management apparatus may proceed to step S1230 again to determine the frequency band that minimizes the correlation between the frequency band-specific impedance and the channel as the set frequency band. For example, the battery management apparatus may determine the frequency band with the minimum average of the RMSE for each channel of the internal temperature as the set frequency band. By repeating this process, the set frequency band may be determined and a learning model that estimates the internal temperature of the battery may be generated using the set impedance corresponding to the set frequency band.

FIG. 14 is a flowchart showing an operation for generating a learning model of a battery management apparatus for each channel according to an embodiment of the present invention.

Referring to FIG. 14, the battery management apparatus may set the internal temperature of the battery at step S1410. For example, the battery management apparatus may set the internal temperature of the battery by using a separate temperature chamber so that the battery and the chamber temperature are in thermal equilibrium.

In an embodiment, the battery management apparatus may obtain the module-specific frequency band-specific impedance for each channel from the impedance measurement unit at step S1420. The battery management apparatus may obtain the impedance across the frequency for each module for each channel from the impedance measurement unit and store the data.

In an embodiment, the battery management apparatus may determine a set frequency band corresponding to a specific channel based on the frequency band-specific impedance and module-specific correlation at step S1430. In an embodiment, the battery management apparatus may determine the frequency band that minimizes the correlation with the module as the set frequency band using the module-specific impedance Bode plot or Nyquist plot. In each battery channel, a set frequency band in which the frequency response characteristics of all modules are similar may be determined and used for the internal temperature estimate.

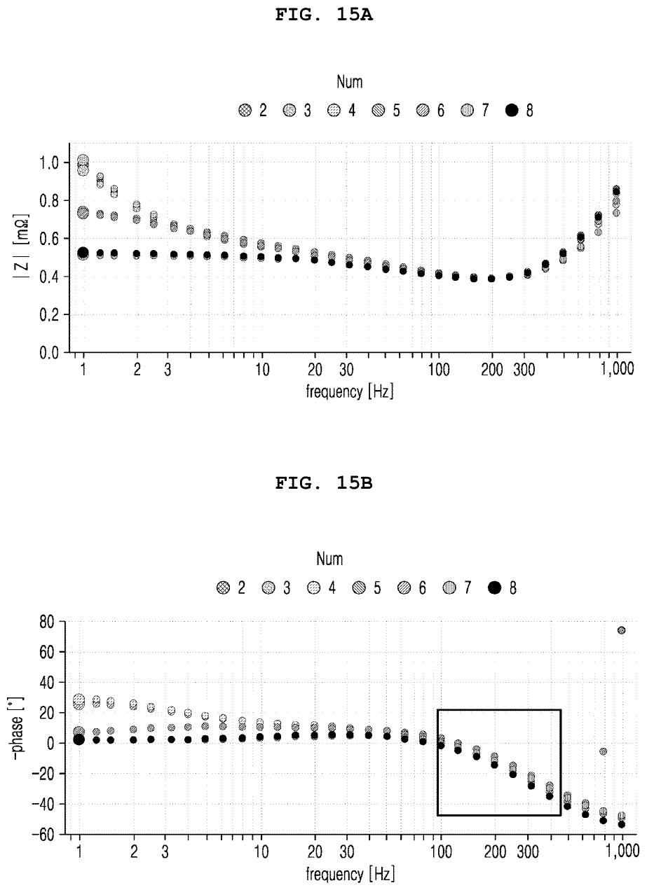

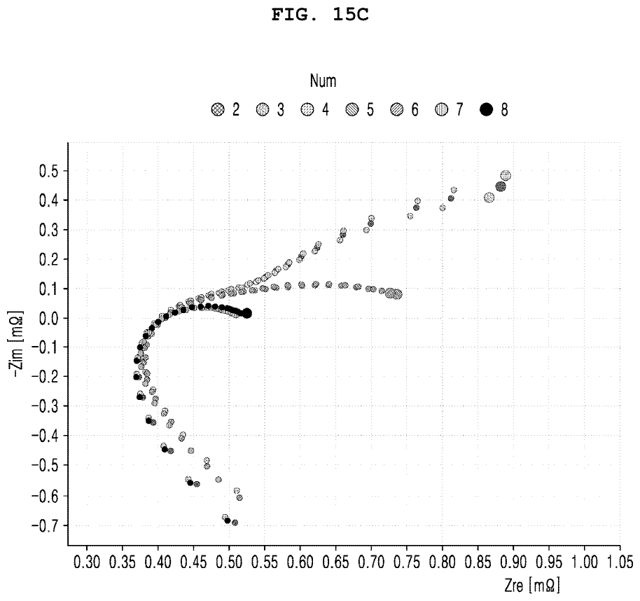

For example, the battery management apparatus may identify a Bode plot for the magnitude of the frequency band-specific impedance with a module-specific legend of a specific channel in the battery pack, as illustrated in FIG. 15A. At this time, it may be confirmed that the correlation between the module and the impedance magnitude is low in a frequency band of 100 hz to 350 hz. The battery management apparatus may determine a set frequency band corresponding to a specific channel in a frequency band with a low correlation between the module and the impedance magnitude.

The battery management apparatus may identify a Bode diagram for the phase of the frequency band-specific impedance with a module-specific legend of a specific channel in the battery pack, as illustrated in FIG. 15B. At this time, it may be confirmed that the correlation between the module and the impedance phase is low in a frequency band of 100 hz to 350 hz. The battery management apparatus may determine a set frequency band corresponding to a specific channel in a frequency band with a low correlation between the module and the impedance magnitude.

The battery management apparatus may identify a Nyquist plot for the phase of frequency band-specific impedance with a module-specific legend of a specific channel in the battery pack, as shown in FIG. 15C. At this time, it may be confirmed that the correlation between the module and the impedance is low in a frequency band of 100 hz to 350 hz. The battery management apparatus may determine a set frequency band corresponding to a specific channel in a frequency band with a low correlation between the module and the impedance magnitude.

In an embodiment, the battery management apparatus may determine set impedance corresponding to the set frequency band among frequency band-specific impedance and a set internal temperature of the battery as a data set at step S1440. Specifically, the battery management apparatus may determine a data set using the impedance data corresponding to the set frequency band among the impedance data regarding the entire frequency range as a feature and the internal temperature data of the battery as a label. For example, the battery management apparatus may determine a data set using at least one of the real number part, the imaginary number part, the magnitude, or the phase of the impedance as a feature and the internal temperature data as a label.

In an embodiment, the battery management apparatus may generate a learning model that estimates the internal temperature of the battery from the set impedance using the data set at step S1450. The learning model is a model that estimates the internal temperature of the battery from the set impedance corresponding to a specific channel, and may be a model based on a GPR or polynomial regression algorithm.

The battery management apparatus according to an embodiment may evaluate the learning model that estimates the internal temperature of the battery from the set impedance at step S1460 and determine the learning model.

The battery management apparatus according to another embodiment may generate a learning model that estimates the internal temperature of the battery from the frequency band-specific impedance at step S1450. That is, the battery management apparatus may generate a learning model that estimates the internal temperature using the impedance across the frequency and module.

In another embodiment, the battery management apparatus may evaluate the learning model that estimates the internal temperature using the impedance across the frequency and module at step S1460. The model performance evaluation may be determined by Mean Square Error (MSE), Root Mean Square Error (RMSE), R2 score, etc. depending on the machine learning model or neural network model. Specifically, the battery management apparatus may confirm the Root Mean Square Error (RMSE) for each module with the estimated internal temperature and the actual internal temperature.

Thereafter, the battery management apparatus may proceed to step S1430 again to determine the frequency band that minimizes the correlation between the frequency band-specific impedance and the module as the set frequency band. For example, the battery management apparatus may determine the frequency band with the minimum average of the module-specific RMSE of the internal temperature as the set frequency band. By repeating this process, the set frequency band may be determined and a learning model that estimates the internal temperature of the battery may be generated using the set impedance corresponding to the set frequency band.

The battery management apparatus may estimate the battery internal temperature in the above embodiments. In addition, the battery management apparatus may estimate the battery internal temperature to perform fire prediction, diagnosis, and management.

Although the embodiments have been described by limited embodiments and drawings as described above, those skilled in the art may make various modifications and variations from the above description. For example, even if the described techniques are performed in a different order from the described method, and/or the components of the described system, structure, device, circuit, etc., are mixed or combined in a different form from the described method, or are replaced or substituted by other components or equivalents, appropriate results can be achieved. In other embodiments consistent with the principles of the present invention, the order of these operations may be changed. In addition, non-dependent operations may be executed in parallel.

For example, impedance measurement may be performed, and internal temperature estimation may be performed, based on a set frequency band determined by the correlation between the set frequency band corresponding to a specific module and the SOC. Alternatively, based on the set frequency band determined by the correlation between the set frequency band corresponding to a specific channel and the SOC, the impedance measurement may be performed, and the internal temperature estimate may be performed.

In addition, a learning model according to the present invention may be generated by a separate computing device including at least one of a GPU, a CPU, and a TPU, and may be stored in a memory of a battery management apparatus or stored in a separate server and provided through communication.

Therefore, other implementations, embodiments, and equivalents to the claims also fall within the scope of the claims described below.

1. A battery management apparatus comprising:
an impedance measurement unit configured to measures frequency band-specific impedance of a battery; and
a controller configured to:
control the impedance measurement unit to apply a signal of a set frequency band to the battery; receive set impedance corresponding to the set frequency band from the impedance measurement unit; and
input the set impedance to a learning model to estimate the internal temperature of the battery,
wherein the learning model is generated based on a data set including the set impedance and the internal temperature of the battery, and
wherein the set frequency band is determined by the correlation between the state of charge (SOC) and the evaluation of the learning model, with respect to the actual internal temperature and the estimated internal temperature.

2. The battery management apparatus of claim 1, wherein the correlation is a correlation that minimizes the average of a Root Mean Square Error (RMSE) between the actual internal temperature and the estimated internal temperature for each state of charge (SOC).

3. The battery management apparatus of claim 1, wherein the learning model is a polynomial regression model between the internal temperature of the battery and the set impedance.

4. The battery management apparatus of claim 1, wherein the controller is configured to transmit a fire risk message when the estimated internal temperature of the battery is equal to or greater than a first threshold.

5. The battery management apparatus of claim 1, wherein the controller is configured to perform a fire diagnosis when the estimated internal temperature of the battery is equal to or greater than a second threshold.

6. The battery management apparatus of claim 5, wherein the controller is configured to perform fire management when a phase change amount of the set impedance over time is equal to or greater than a third threshold.

7. A battery management method comprising:
measuring, by an impedance measurement unit, set impedance corresponding to a set frequency band; and
estimating, by inputting the set impedance to a learning model, the internal temperature of a battery,
wherein the learning model is generated based on a data set including the set impedance and the internal temperature of the battery, and
wherein the set frequency band is determined by the correlation between the state of charge (SOC) and the evaluation of the learning model, with respect to an actual internal temperature and an estimated internal temperature of the battery.

8. The battery management method of claim 7, wherein the correlation is a correlation that minimizes the average of a Root Mean Square Error (RMSE) between the actual internal temperature and the estimated internal temperature for each state of charge (SOC).

9. The battery management method of claim 7, further comprising transmitting a fire risk alert when the estimated internal temperature of the battery is equal to or greater than a first threshold.

10. The battery management method of claim 7, further comprising performing a fire diagnosis when the estimated internal temperature of the battery is equal to or greater than a second threshold.

11. The battery management method of claim 10, wherein the performing of the fire diagnosis comprises performing fire management when a phase change amount of the set impedance over time is equal to or greater than a third threshold.
